(19) United States
(12) Patent Application Publication
(10) Pub. No.: US 2007/0186135 A1
(43) Pub. Date: Aug. 9, 2007

(54) Processor system and methodology with background error handling feature

(76) Inventors: Brian Flachs, Georgetown, TX (US); H. Peter Hofstee, Austin, TX (US); John S. Liberty, Round Rock, TX (US); Brad W. Michael, Cedar Park, TX (US)

Correspondence Address: MARK P. KAHLER, 8101 VAILVIEW COVE, AUSTIN, TX, 78750, US

(21) Appl. No.: 11/351,121

(22) Filed: Feb. 9, 2006

(51) Int. Cl. H03M 13/00

(52) U.S. Cl. 714/752

(57) ABSTRACT

A processor system is disclosed that integrates error correcting code (ECC) detection and correction hardware within an memory management circuit. ECC hardware circuitry provides detection, correction and generation of ECC data bits in conjunction with memory data read and writes. The disclosed methodology permits the detection and correction of soft single bit errors read from local memory in-line while using read modify write DMA circuit logic to correct local memory data. The disclosed methodology provides local memory data error detection and correction in a background memory scrub process without the need for additional in-line data logic.

### TECHNICAL FIELD OF THE INVENTION

The disclosures herein relate generally to information handling systems, and more particularly, to information handling systems that employ error correction code memory.

### BACKGROUND

A processor and local memory system may employ data error detection and correction mechanisms to increase the accuracy and effectiveness of processor to memory data read and write operations. Memory data error detection and correction mechanisms play important roles in information handling systems (IHSs) such as desktop, laptop, notebook, personal digital assistant (PDA), server, mainframe, minicomputer, graphics processors, communication systems, and other systems that employ digital electronics.

For example, a soft error may occur at a memory location or cell wherein a stored bit changes value without the memory system intentionally changing that bit value. The passage of a high energy particle through the memory cell may cause this soft error that alters the bit value of the memory cell. Operating a memory system at or near maximum speed or voltage ratings can induce soft errors as well. Error detection mechanisms may detect soft errors. However, in conventional error checking and correction (ECC) mechanisms, the ECC mechanism that detects an error may not immediately know the memory location associated with the error at the time of error detection. If the memory location is not known at the time of error detection, a correction of the soft error bit in memory can lead to significant software intervention, as well as additional hardware apparatus and consumption of processing time.

What is needed is an error handling apparatus that detects and corrects errors without using substantial additional hardware and which operates in a time efficient manner.

### SUMMARY

Accordingly, in one embodiment, a method of handling information in a processor system is disclosed that includes storing data words and respective associated error correction codes in a local memory coupled to a processor included in the processor system. The method also includes retrieving, by an error detection and correction circuit, a selected data word and associated error code from the local memory. The method further includes forwarding, by the error detection and correction circuit, the selected data word to the processor if the selected data word exhibits no error. The method still further includes correcting, by the error detection and correction circuit using in-line error correction, the selected data word if the selected data word exhibits a correctable error to provide a corrected data word that is sent to both the processor and the local memory. The method also includes signaling, by the error detection and correction circuit, an uncorrectable error condition to an error controller if the selected data word exhibits an uncorrectable error. Moreover, the method further includes initiating, by the error controller, out-of-line error correction operations to correct correctable errors.

In another embodiment, a processor system is disclosed that includes a first processor. The processor system also includes a local memory that stores data words and respective associated error correction codes local to the first processor. The processor system further includes a system memory port for coupling to a system memory that stores data words and supplies data words to the local memory. The processor system still further includes direct memory address (DMA) circuitry coupling the local memory to the system memory port. The processor system also includes error detection and correction circuitry, coupled to the local memory and the first processor and the DMA circuitry, that retrieves a selected data word from the local memory. The error correction and detection circuitry uses in-line error correction to correct the selected data word if the selected data word exhibits a correctable error to provide a corrected data word that is sent to both the first processor and the local memory. The processor system also includes an error controller, coupled to the error detection and correction circuitry, that receives error information from the error detection and correction circuitry. The error controller initiates out-of-line error correcting operations to correct correctable errors indicated by the error information received from the error detection and correction circuitry. In one embodiment, the processor system includes a second processor coupled to the system memory port.

### BRIEF DESCRIPTION OF THE DRAWINGS

The appended drawings illustrate only exemplary embodiments of the invention and therefore do not limit its scope because the inventive concepts lend themselves to other equally effective embodiments.

FIG. 1 shows a block diagram of the disclosed processor system.

FIG. 2 shows a more detailed block diagram of the circuitry of FIG. 1.

FIG. 3 shows a flow diagram that depicts a DMA read process used in the disclosed processor system.

FIG. 4 shows a flow diagram that depicts an ECC scrub operation of the method implemented in the disclosed processor system.

FIG. 5 shows a flow diagram that depicts a mechanism for reading local memory according to the method implemented in the disclosed processor system.

FIG. 6 shows a flow diagram that depicts an instruction fetch mechanism of the method implemented in the disclosed processor system.

### DETAILED DESCRIPTION

In a cache-based memory system, a processor may access a main system memory via a cache memory. The processor reads the cache memory as though it were reading directly from system memory. Cache memory maintains a copy of data that the system also stores in system memory. Accesses to memory locations in the cache memory typically take much less time to fetch than accesses to system memory. In general, the cache memory loads when the processor makes a request for data at a system memory location that is not currently stored in the cache memory. The cache memory hardware will cast out an older piece of data to system memory if the system modifies that data, and overwrite the memory location with the newer requested data. While the system fetches such data, the processor may stall waiting for the fetch to complete.

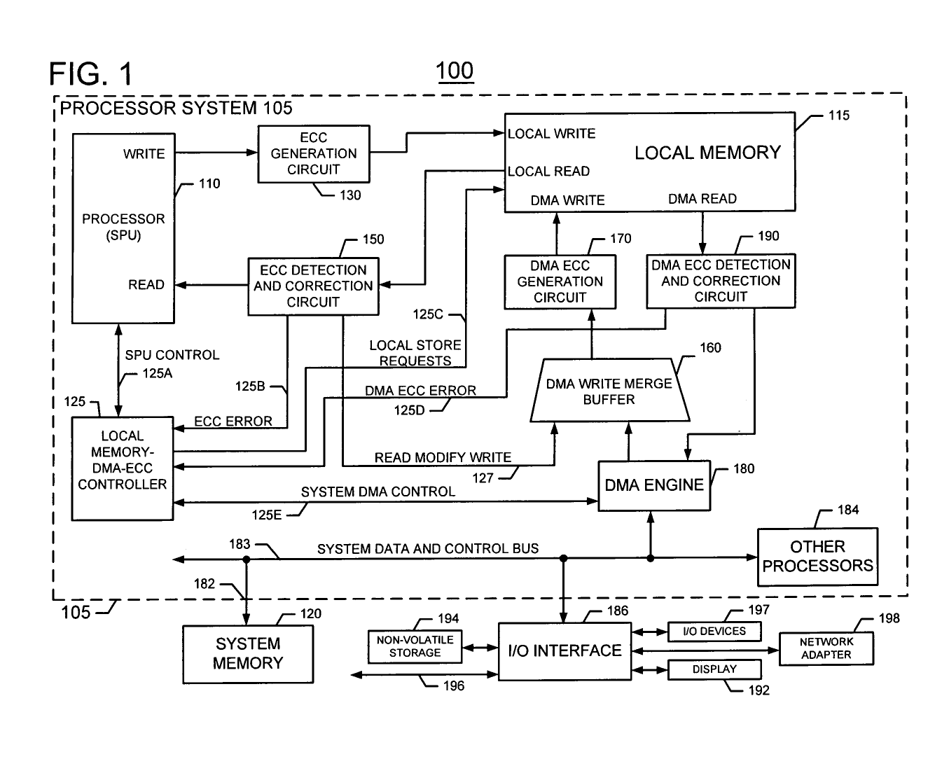

In one embodiment of the disclosed technology, an information handling system (IHS) 100 includes a processor system 105 having a processor 110, such as the synergistic processor unit (SPU) as shown in FIG. 1, wherein processor 110 directly accesses a local memory store 115 rather than a cache memory. System memory 120 couples to the local memory store 115 via a direct memory access (DMA) system. Once a local memory load completes, the processor 110 directly accesses local memory 115 for read and write operations. Accessing local memory in this manner increases the speed of memory operations initiated by processor 110. In one embodiment, processor system 105 includes no cache memory associated with processor or SPU 110. In cache memory systems, the CPU looks to system memory when the cache memory does not contain the desired data. However, in one embodiment, the disclosed processor system 105 configures SPU 110 such that SPU 110 looks to local memory 110 for desired data rather than a system memory

The local memory 115 associated with the processor or SPU 110 may employ a read modify write path to allow data to read from local memory, modify and write back to the local memory via a DMA write operation. Processor 110 may also employ read modify write (RMW) circuits to allow modification of memory locations without full processor read/write bus cycles. Memory read operations may involve more than a single bit error. In cases where a memory read operation encounters a two bit or greater error during the read operation, in-line error correction is not feasible. With “in-line” error correction, processor system 105 corrects an error during the current read cycle. With “out-of-line” error correction, processor system 105 corrects the error over multiple read cycles. “Out-of-line” error correction may be viewed as error correction not “in-line”. However, when processor system 105 detects an uncorrectable multi-bit error, the system stops and signals that an error has occurred. One embodiment of the disclosed processor system employs an error detection apparatus that determines single memory bit errors during a memory read operation and further provides in-line memory bit error correction. Another embodiment of the processor system employs an error detection apparatus that determines two bit or greater memory errors during a memory read operation and provides memory correction via background memory scrubbing operations. Memory scrubbing refers to periodically reading data from memory, checking the data thus read for single bit errors and correcting those single bit errors.

In one embodiment, processor system 105 may exhibit a configuration that includes multiple processors or SPUs 110 such as described in “IBM—Cell Broadband Engine Architecture”, Version 1.0, Aug. 8, 2005, which is incorporated herein by reference in its entirety.

FIG. 1 shows a processor system 105 that operates in one of four modes listed below in Table 1. A controller 125, namely local memory-DMA-ECC controller circuit 125, initiates and controls the operation of processor system 105 in one of the four modes of Table 1.

TABLE 1

| Mode | |
|---|---|
| (in priority order) | Mode Description |
| 1 | DMA Read/Write |
| 2 | ECC Scrub |
| 3 | SPU Read/Write |
| 4 | SPU Instruction Fetch |

Modes 1 describes an operational mode with the highest priority. Direct memory access (DMA) operations provide a mechanism to read or write local memory 115 using a continuos addressing methodology. A DMA operation writes the contents of system memory 120 into local memory 115 or reads from local memory 115 and transfers the contents thus read into system memory 120. Mode 2 represents the next highest priority and describes an error correcting code (ECC) scrub operation. This ECC scrub operation involves correcting a data bit error in local memory 115 through a method of reading local memory 115, checking the validity of the memory data therein, and writing valid data back into local memory 115 when the method detects an error in the memory data thus read. In processor system 105, the ECC scrub operation may operate as a background task, thus providing limited impact on the normal operation of processor system 105. A background task exhibits a priority less the normal operational priorities of processor 110.

Mode 3 describes processor system 105 in one normal operating mode of reading from, and writing data to, local memory 115. In one embodiment, mode 3 corresponds to an SPU memory read/write operation. During a memory write operation, processor system 105 generates ECC data and writes the ECC data to local memory 115 along with the memory data. Processor system 105 may detect errors during a memory read operation. ECC correction circuitry in processor system 105 provides a mechanism that corrects single bit errors in-line, meaning single bit errors within the data path. Finally, mode 4 represents the lowest priority operation within processor system 105. An SPU instruction fetch describes an operation wherein the processor or SPU 110 reads sequential data from local memory 115 and operates on that data as a series of instructions. In a scenario wherein a local memory read operation yields an invalid data bit, and the address to the local memory remains valid and available, processor system 105 corrects the memory data location by using a read modify write (RMW) path 127 of DMA circuitry in the processor system 105.

The local memory-DMA-ECC controller 125 couples to processor or SPU 120 via a control signal bus 125A to control the operation SPU 110 with respect to error handling. SPU 110 includes a write output that couples to the input of an error correcting code (ECC) generation circuit 130. ECC generation circuit 130 evaluates the write data output of processor 110, namely a data word, and generates an associated error correction code for that data word. The error correction code combines with the write data output within the ECC generation circuit 130 to form the output signal of ECC generation circuit 130. The output of ECC generation circuit 130 couples to the local write input of a local memory 115. The combination of the write data bits with ECC data bits from the ECC generation circuit 130 forms the local write data at the local write input of local memory 115.

Processor system 105 uses error correcting codes (ECC) as a tool to both detect and correct corrupted memory data locations. One embodiment of the disclosed methodology uses data in 128 bit groups, namely one quad word. The R. W. Hamming code for 128 bit ECC requires the attachment of 9 additional bits of data to the 128 bit quad word data in memory to detect and correct a single bit error. Additionally, such error detecting and error correcting codes (ECC) can determine if the 128 bit quad word includes two or more bits corrupted in memory. In the case where multiple memory location bits are invalid, the 9 bit ECC code is unable to provide sufficient information to correct the data without additional DMA memory operations.

The local read output of local memory 115 couples to the input of an ECC detection and correction circuit 150. ECC detection and correction circuit 150 evaluates read data from local memory 115 as a result of addressing control that local memory-DMA-ECC controller 125 supplies, as described below. Controller 125 couples to local memory 115 via local store requests bus 125C. Local memory-DMA-ECC controller 125 generates local store request signals. The ECC detection and correction circuit 150 provides the memory read data to the read input of processor 110 if circuit 150 evaluates the read data as valid and without error. ECC detection and correction circuit 150 can correct read data in-line if circuit 150 determines that the read data from local memory 115 contains a single bit error. ECC detection and correction circuit 150 employs Hamming ECC correction algorithms to correct data exhibiting a single bit error.

An ECC error signal bus 125B couples to an input of local memory-DMA-ECC controller 125 to provide information regarding any errors that circuit 150 detects during a local memory read operation.

Some errors that ECC detection and correction circuit 150 detects and corrects retain a valid memory address location to local memory 115. In these cases, local memory-DMA-ECC controller 125 initiates a read modify write (RMW) operation to correct that specific address location in local memory 115. Read modify write signal bus 127 contains the corrected local read data from ECC detection and correction circuit 150. ECC detection and correction circuit 150 couples to one of two inputs of a DMA write merge buffer 160 through read modify write signal bus 127. DMA write merge buffer 160 couples to and provides corrected memory data to a DMA ECC generation circuit 170. As local memory-DMA-ECC controller 125 holds a local store request active with signal bus 125C to local memory 115, DMA ECC generation circuit 170 generates associated ECC code bits for the data to be written in local memory 115. DMA ECC generation circuit 170 couples to and provides corrected memory data and ECC code bits to the DMA write input of local memory 115.

Other errors that ECC detection and correction circuit 150 detects and corrects do not have a corresponding valid local memory 115 address. In these cases, local memory-DMA-ECC controller 125 cannot initiate a read modify write (RMW) operation. ECC detection and correction circuit 150 generates corrected data which it supplies to processor or SPU 110. However, the bad memory data still resides within local memory 115. In this case, local memory-DMA-ECC controller 125 initiates an ECC scrub operation in the background to systematically read local memory and repair or replace erroneous data.

In some cases, ECC detection and correction circuit 150 detects data read errors containing more than one bit of corrupted data. In this condition, ECC detection and correction circuit 150 cannot correct the data in-line. In such an un-correctable read condition, processor system 105 operations halt and system 100 signals an error on bus 183. Continuing with the description of local memory-DMA-ECC controller 125, as seen in FIG. 1, controller 125 couples to a DMA engine 180 by a system DMA control signal bus 125E. Local memory-DMA-ECC controller 125 generates a DMA request by communicating with DMA engine 180 through signal bus 125E.

To enable DMA write operations to local memory 115, DMA engine 180 couples to a system memory 120, other processors 184, and an I/O interface 186 through a system data and control bus 183. DMA engine 180 generates a request for DMA load of local memory 115 from the contents of system memory 120. Address by address, system memory 120 provides its data contents to DMA engine 180, the output of which couples to the second of two inputs of DMA write merge buffer 160. The output of DMA write merge buffer 160 supplies DMA ECC generation circuit 170 with each write data word. DMA ECC generation circuit 170 analyzes the DMA write data word and generates a proper ECC code to accompany the write data word presented to the DMA write input of local memory 115. The DMA operation continues until all memory in the local memory 115 restores to valid data.

The DMA read output of local memory 115 couples to a DMA ECC detection and correction circuit 190. During a DMA read operation, local memory 115 data presents to DMA ECC detection and correction circuit 190 one word at a time. DMA ECC detection and correction circuit 190 couples to local memory-DMA-ECC controller 125 through a DMA ECC error bus 125D. Local memory-DMA-ECC controller 125 receives error data regarding information about the data bit error, if DMA ECC detection and correction circuit 190 detects a single bit error during the DMA read operation. DMA ECC detection and correction circuit 190 also couples to DMA engine 180. DMA ECC detection and correction circuit 190 generates corrected DMA read data and provides corrected read data to DMA engine 180. DMA engine 180 presents the corrected DMA read data to system memory 120 through system data and control bus 183. In one embodiment, DMA engine 180 may share data with other processors 184 and devices outside of processor system 105 through I/O interface 186.

In one embodiment, information handling system (IHS) 100 includes an optional display 192 that couples via a video graphics controller (not shown) to I/O interface 186. Nonvolatile storage 194, such as a hard disk drive, CD drive, DVD drive, or other nonvolatile storage couples to I/O interface 186 to provide IHS 100 with permanent storage of information. An operating system loads in system memory 120 to govern the operation of IHS 100. I/O devices 197, such as a keyboard and a mouse pointing device (not shown), may also couple to I/O interface 186. One or more expansion busses 196, such as USB, IEEE 1394 bus, ATA, SATA, PCI, PCIE and other busses, couple to bus I/O interface 186 to facilitate the connection of peripherals and devices to IHS 100. A network adapter 198 couples to I/O interface 186 to enable IHS 100 to connect by wire or wirelessly to a network and other information handling systems. System memory 120 couples to a system memory port 182 of processor system 105. In one embodiment, a semiconductor fabrication facility may build processor system 105 as an integrated circuit, in which case the dashed line 105 in FIG. 1 represents a semiconductor substrate together with the logic depicted in FIG. 1.

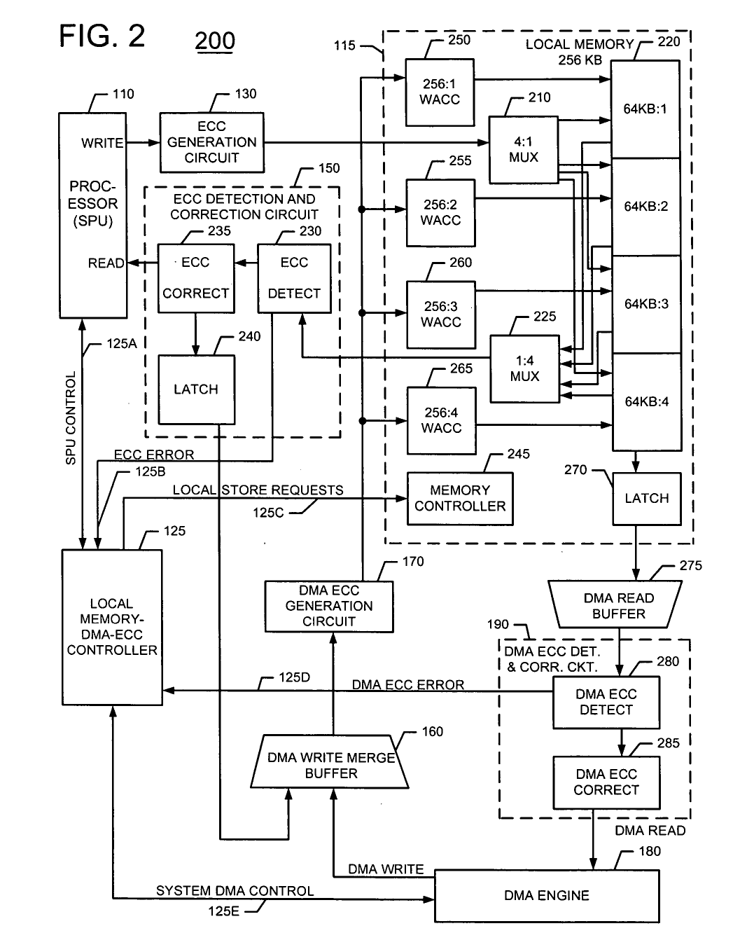

FIG. 2 shows a processor system 200, namely a more detailed block diagram of the processor system 105 of FIG. 1. In comparing FIG. 2 with FIG. 1, like numbers indicate like components. Processor system 200 includes local memory-DMA-ECC controller 125 coupled to processor or SPU 110 that receives SPU control signals from SPU control bus 125A. The write data output of processor 120 couples to the input of ECC generation circuit 130. Processor 120 generates a 128 bit quad word output from which ECC generation circuit 130 creates a 9 bit ECC code corresponding to the quad word data. The output of ECC generation circuit 130, which generates a 128 plus 9 bit data structure, couples to local memory 115 as shown. More specifically, the output of ECC generation circuit 130 couples to a 4:1 multiplexer (MUX) 210 within local memory 115. 4:1 MUX 210 divides the quad word data into four equal memory words of 32 bits each. 4:1 MUX 210 includes four outputs that couple respectively to four 64 KB memory input locations, 64 KB: 1, 64 KB:2, 64 KB:3, and 64 KB:4 of memory 220. In total, all four 64 KB memory circuits in memory 220 provide a 256 KB memory store for local memory 115.

Each of the four 64 KB memory circuits 220 couples to one of four input of a 1:4 MUX 225. During a local memory read operation, 1:4 MUX 225 reads 256 bits each from the four 64 KB memory circuits of memory 220 for a total memory read of 1 KB. 1:4 MUX 225 stores 1 KB of 128 quad words in a succession of 8 cycles of 128 bit quad words each with ECC data of 9 bits attached. 1:4 MUX 225 couples to the input of an ECC error detection circuit 230 in ECC error detection and correction circuit 150. The output of ECC error detection circuit 230 couples to the input of ECC error correction circuit 235. ECC error detection circuit 230 couples to the input of local memory-DMA-ECC controller 125 via ECC error bus signal input 125B. If ECC error detection circuit 230 evaluates a read error, then circuit 230 provides the resulting information associated with the error to local memory-DMA-ECC controller 125. ECC correct circuit 235, which corrects single bit errors of the 128 bit quad word read, couples to the read input of processor 120 and the input of a latch 240 as shown.

An output of local memory-DMA-ECC controller 125 couples via local store request bus to a memory controller circuit 245 of local memory 115. Local memory-DMA-ECC controller 125 initiates local memory read and write requests. Memory controller 245 controls local memory read and write requests within local memory 115. The output of latch 240 of ECC circuit 150 couples to one of two inputs of DMA write merge buffer 160. The output of DMA write merge buffer 160 couples to the input of DMA ECC generation circuit 170 as part of a DMA read modify write implementation.

The output of DMA write merge buffer 160 couples via DMA ECC generation circuit 170 to each of four 256 bit write accumulators (WACCs) in local memory 115, specifically WACC 250 also designated 256:1, WACC 255 also designated 256:2, WACC 260 also designated 256:3 and WACC 265 also designated 256:4 in FIG. 2. Each 256 bit accumulator receives 32 bits of output data from DMA ECC generation circuit 170. After an accumulation of 8 data outputs from ECC generation circuit 170, each 256 bit WACC circuit contains 8×32 or 256 bits of data for writing to local memory 115. The output of 256:1 WACC 250 couples to the input of 64 KB:1 of memory 220. The output of 256:2 WACC 255 couples to the input of 64 KB:2 of memory 220. The output of 256:3 WACC 260 couples to the input of 64 KB:3 of memory 220. Finally, the output of 256:4 WACC 265 couples to the input of 64 KB:4 of memory 220. After 8 data write operations complete at the input of local memory 115, the four 256 bit WACC circuits 250, 255, 260, 265 write 1 KB of data into local memory 115 in a single write cycle.

Local memory-DMA-ECC controller 125 couples to a DMA engine 180 via system DMA control signal bus 125E. DMA engine 180 provides the necessary logic to generate DMA operational control and an interface for processor system 200. The output of DMA engine 180 couples to an input of DMA write merge buffer 160. DMA write merger buffer 160 provides a data path for DMA data writes into local memory 115.

The input of a latch 270 couples to the output of the 64 KB memory circuits 220. In a single DMA read operation, latch 270 holds 1 KB of data in this particular embodiment. The output of latch 270 couples to the input of DMA read buffer 275. During a DMA read operation, DMA read buffer 275 accumulates DMA read data from local memory 115. The output of DMA read buffer 275 couples to the input of a DMA ECC detect circuit 280 of DMA ECC detection and a correction circuit 190. DMA ECC detect circuit 280 couples local memory-DMA-ECC controller circuit 125 via DMA ECC ERROR bus 125D. In conditions wherein DMA ECC detect circuit 280 encounters errors during DMA reads, DMA ECC detect circuit 280 provides DMA ECC error data to local memory-DMA-ECC controller circuit 125. An output of DMA ECC detect circuit 280 couples to the input of a DMA ECC error correct circuit 285. The output of DMA ECC error correct circuit 285 couples to DMA engine 180 as shown.

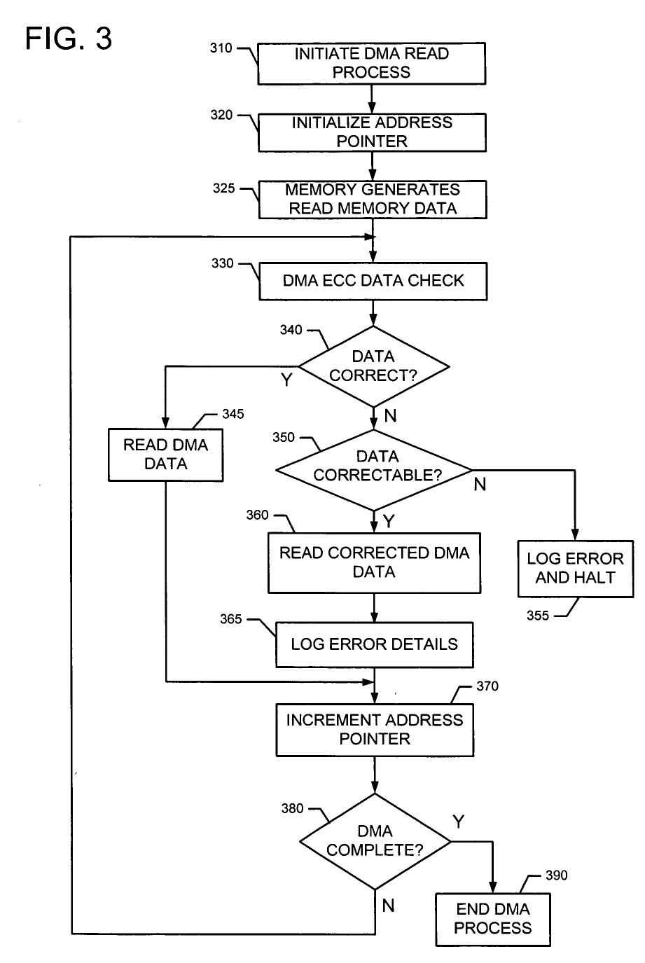

FIG. 3 shows a flow diagram which depicts a DMA read operation in one embodiment of the method implemented in the disclosed processor system 105. The DMA read operation begins by initiating a DMA read process, as per block 310. In this embodiment, each memory location in local memory 115 stores 128 bits of read data (a quad word) and 9 bits of associated ECC data. Local memory-DMA-ECC controller 125 generates a local store request signal on bus 125C. Processor system 105 initializes an address pointer data at an input of local memory 115, as per block 320. In response to address pointer data, local memory 115 generates memory read data at a DMA read output, as per block 325. DMA ECC detection and correction circuit 190 determines the validity of DMA read data by performing a DMA ECC data check, as per block 330. DMA ECC detection and correction circuit 190 next interprets the 9 bits of ECC data associated with 128 bits of memory data to determine if the data contains any invalid bits, as per a decision block 340. In other words, decision block 340 determines the correctness of the data. If decision block 340 determines that all data bits are correct, then process flow continues to block 345 at which DMA engine 180 reads the DMA data. DMA engine 180 buffers the valid DMA read data to system data and control bus 183. System memory 120 then receives DMA read data from DMA engine 180 as input.

Returning now to decision block 340, DMA ECC detection and correction circuit 190 determines if the DMA read data contain any invalid bits. Circuit 190 then further tests to determine if any invalid DMA read data are correctable in-line without the need for reload from external memory sources, as per block 350. In other words, DMA ECC detection and correction circuit 190 determines if the read data is correctable in-line within processor system 105. If two or more data bits are invalid in the entire 128 bits of read data, then processor system 105 data can not correct the data in-line. If circuit 190 determines that the data is not correctable, then processor system 105 logs the error and the DMA read process halts, as per block 355. If a single bit of data evaluates as invalid, the error is correctable and DMA ECC detection and correction circuit 190 detects and corrects the 128 bit memory data. Further, DMA ECC detection and correction circuit 190 presents the corrected 128 data bits to DMA engine 180, as per block 360. DMA engine 180 in turn presents the valid DMA read data to system data and control bus 183. System data and control bus 183 presents the valid DMA read data to system memory 120 as well as I/O interface 186 and other processors 184 as needed. Local memory-DMA-ECC controller 125 then logs any ECC error information, as per block 365. The address pointer then increments to the next address location pointer, as per block 370. Moreover, following the path wherein lock 345 reads the DMA data, local memory address pointer increments per block 370.

Next, the DMA read process conducts a test at decision block 380 to determine if the DMA read operation is complete. If the DMA read operation is not complete, then process flow continues back to block 330 that performs the next ECC data check and continues. However, if decision block 380 finds that the DMA process is complete, then the DMA process ends, as per block 390.

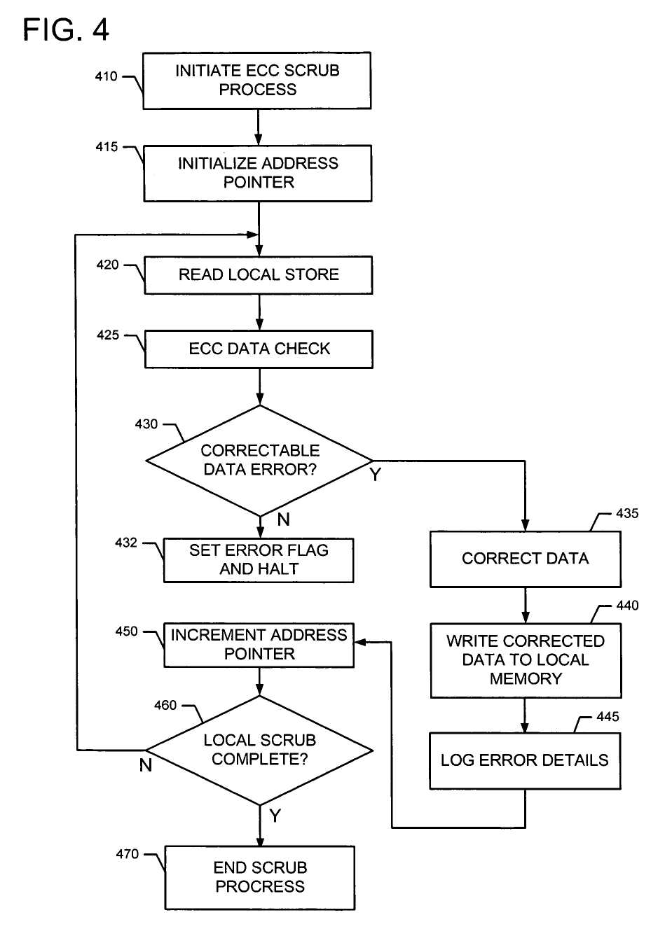

FIG. 4 depicts a flow diagram of the ECC scrub process that one embodiment of the disclosed processor system 105 employs. Local memory-DMA-ECC controller 125 initiates an ECC scrub process, as per block 410. Local memory 115 receives the initialized address pointer data that local memory-DMA-ECC controller 125 generates on local store requests bus 125C, as per block 415. The address pointer data may be a pointer to a known bad data location as logged previously by processor system 105 during a read and subsequent error detection of a local memory operation. Local memory 115 performs a read operation as per an input request on local store requests bus 125C from local memory-DMA-ECC controller 125. Local memory 115 presents memory data as 128 bits with 9 ECC bits as output at a local read data output, as per block 420. ECC detection and correction circuit 150 performs an ECC data check of local memory data, as per block 425. ECC detection and correction circuit 150 conducts a test to determine if the data evaluates to one bit of error and is thus correctable, as per decision block 430. If the data evaluates to a multi-bit error, namely an uncorrectable error, then processor system 105 sets an error flag and halts, as per block 432. Thus, when processor system 105 encounters an uncorrectable error, the processor system logs the error and then halts. It is then up to the user to determine the proper course of action. In one embodiment, the scrubbing process ignores uncorrectable errors. Returning to decision block 430, if the data evaluates to a single bit error, namely a correctable error, then ECC detection and correction circuit 150 generates a correction of the read data in-line, as per block 435. ECC detection and correction circuit 150 then presents the corrected data to DMA write merge buffer 160.

DMA write merge buffer 160 buffers the corrected memory data to DMA ECC generation circuit 170. DMA ECC generation circuit 170 generates a new ECC code of 9 bits for each 128 bits of valid data. ECC generation circuit 170 writes the entire 137 bits of corrected data to local memory 115 at DMA write input, as per block 440. Utilizing the DMA write input of local memory 115, processor system 105 employs a read modify write (RMW) mechanism. Using RMW circuitry within the processor system for data repair involves no additional RMW circuitry. Processor system 105 logs data error details such as address location and detected data bit that ECC error bus 125B communicates to local memory-DMA-ECC controller 125, as per block 445. Process flow then continues to block 450 at which processor system 105 advances to the next address in local memory 110 by incrementing the address pointer.

Next, local memory-DMA-ECC controller 125 determines if the ECC scrub process is complete, as per decision block 460. If the ECC scrub process is not complete, the processor system 105 initiates the next read of local store data as per block 420 and the ECC scrubbing process repeats. However, if the local memory-DMA-ECC controller 125 determines that the ECC scrub process is complete, then the scrub process ends, as per block 470.

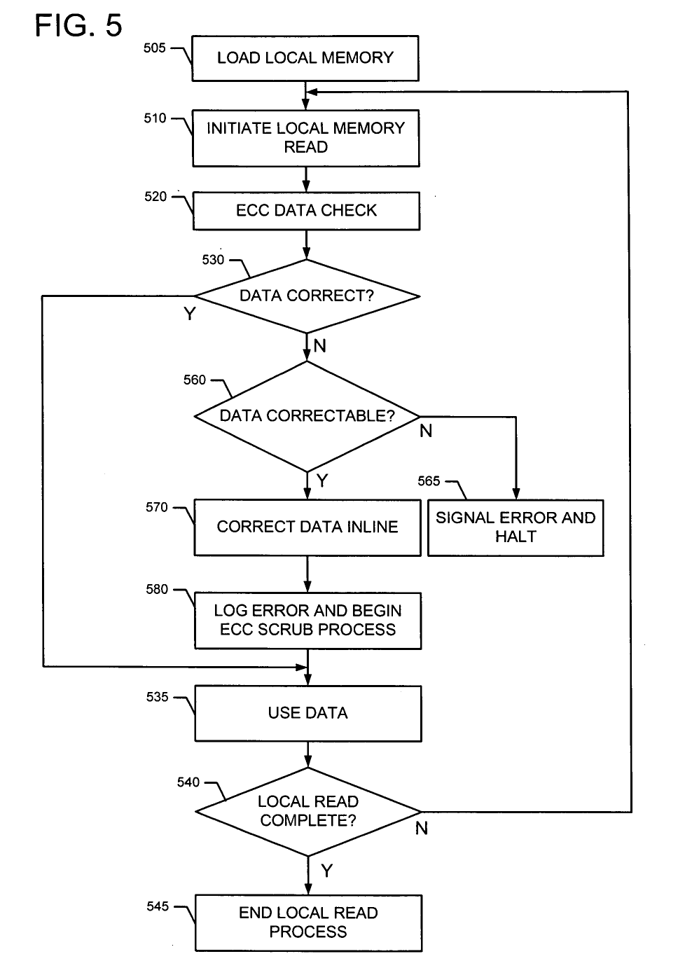

FIG. 5 shows a flow chart that depicts a local memory read operation conducted by one embodiment of the disclosed processor system 105. At power up, processor system 105 includes an empty local memory store 115 that contains no memory data. System memory 120 populates the empty local memory 115 with data, as per block 505. A conventional DMA operation typically supports the load or population of local memory data. After the local memory load process, processor 110 begins normal operations such as reading from local memory 115. Local memory-DMA-ECC controller 125 initiates a local memory read, as per block 510. ECC detection and correction circuit 150 receives memory data that the local read output of local memory 115 generates. ECC detection and correction circuit 150 performs an ECC data check on the local read data, as per block 520. Next, ECC detection and correction circuit 150 performs a test to determine the correctness or validity of the local read data. In other words circuit 150 determines if the read data contains any bit errors, as per block 530. If the local read data evaluates as valid per tests within ECC detection and correction circuit 150, the output of ECC detection and correction circuit 150 then buffers the local read data to the read input of processor or SPU 110. Then process flow continues to block 535 wherein processor 110 uses the local memory read data as input, as per block 535. Then local memory-DMA-ECC controller 125 performs a test to determine if the local memory read operation is complete, as per decision block 540. If the local memory read operation evaluates as complete, then the local memory read process ends, as per block 545. If the local memory read process evaluates as not complete, then process flow continues back to the initiate next local memory read block 510 and the read process continues.

Returning to decision block 530, ECC detection and correction circuit 150 may determines the data read to be not correct or invalid. A one bit error corresponds to a correctable error. An error of more than one bit represents an uncorrectable error. Decision block 560 performs a test to determine if the read data is correctable in-line. If the data error determines to be a single bit error, then process flow continues to block 570 at which the ECC circuitry of ECC detection and correction circuit 150 corrects the data in-line. Returning to block 560, some errors can not be corrected in-line. If decision block 560 determines that a particular error is not correctable, namely the error includes more than one bit, then the memory read process halts as per block 565 and local memory-DMA-ECC controller 125 logs any resultant error information.

Returning to decision block 560, if the data read evaluates correctable, as with single bit errors, then ECC detection and correction circuit 150 corrects the current data, as per block 570. Then local memory-DMA-ECC controller 125 logs any error data, as per a block 580 and, at a later time, an ECC scrub process initiates to correct the data within local memory 115. The current corrected data presents as valid data to the read input of the processor 110 and the process continues at block 535 until the load read completes.

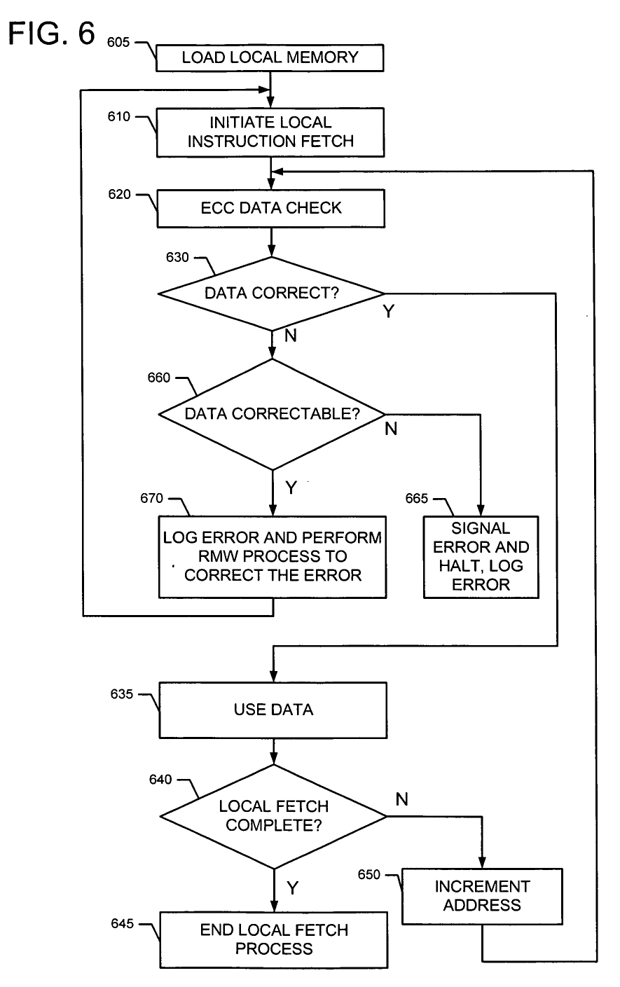

FIG. 6 shows a flowchart that depicts process flow in one embodiment of the disclosed processor system 105 when operating in a local instruction fetch mode. The depicted process flow describes an “out-of-line” error correction for correctable errors, namely error correction of a correctable error performed over more than one read cycle. At power-up processor system 105 contains an empty local memory store 115. A conventional DMA process may populate local memory with data from system memory 120, as per block 605. After the local memory load process, processor or SPU 110 initiates normal operational modes. One mode of operation is the local instruction fetch process. During a local instruction fetch, local memory 115 initializes with a start address and processor 110 reads the start address and each subsequent address as instruction data to the processor 110. Local memory-DMA-ECC controller 125 increments addresses successively with each memory address read and supplies the addresses to local memory 115.

After local memory-DMA-ECC controller 125 initiates a local instruction fetch, as per block 610, ECC detection and correction circuit 150 receives the memory data generated at the local read output of local memory 115. ECC detection and correction circuit 150 performs an ECC data check on the local read data, as per block 620.

ECC detection and correction circuit 150 then determines the local instruction fetch data validity and determines if the read data contains any bit errors, as per decision block 630. If the local instruction fetch data evaluates as valid per tests within ECC detection and correction circuit 150, the output of ECC detection and correction circuit 150 buffers the local instruction fetch data to the read input of SPU 120. For such correct data, process flow continues to block 635 at which processor 110 uses the local memory read data as processor instruction input.

Next, as per decision block 640, local memory-DMA-ECC controller 125 determines if the local memory read operation or fetch evaluates complete. If the local memory instruction fetch operation evaluates as complete, then the local instruction fetch process ends, as per block 645. However, if at decision block 640 the local memory read process evaluates as not complete, then local memory-DMA-ECC controller 125 increments the address to local memory, as per block 650. Local memory-DMA-ECC controller performs the next instruction fetch ECC data check, as per block 620. ECC detection and correction circuit 150 performs the check and the process continues to block 630.

At decision block 630, ECC detection and correction circuit 150 determines the data read to be invalid if any bit of the instruction fetch data evaluated against the ECC code shows an error. If decision block 630 finds such an error in the local memory instruction fetch data, then correction circuit 150 tests the local memory instruction fetch data, as per decision block 660, to determine if the error is correctable in-line. If the data error evaluates to a multiple bit error, the ECC circuitry of ECC detection and correction circuit 150 can not correct the data in-line. In this case, the process halts and the local memory-DMA-ECC controller 125 logs information regarding the instruction fetch data error, as per block 665.

However, if decision block 660 evaluates the data read error as correctable, as with single bit errors, then processor system 105 logs the error data results and initiates a read modify write (RMW) operation to correct the data within local memory 115 during the current cycle, as per block 670. At the completion of the RMW scrub repair, processor system 105 reissues the fetch, as per block 610 and the process continues until the local instruction fetch process completes.

The foregoing describes a processor system that in one embodiment employs local store memory and DMA data paths to perform ECC memory corrections with a minimum amount of hardware.

Modifications and alternative embodiments of this invention will be apparent to those skilled in the art in view of this description of the invention. Accordingly, this description teaches those skilled in the art the manner of carrying out the invention and is intended to be construed as illustrative only. The forms of the invention shown and described constitute the present embodiments. Persons skilled in the art may make various changes in the shape, size and arrangement of parts. For example, persons skilled in the art may substitute equivalent elements for the elements illustrated and described here. Moreover, persons skilled in the art after having the benefit of this description of the invention may use certain features of the invention independently of the use of other features, without departing from the scope of the invention.

What is claimed is:

1. A method of handling information in a processor system comprising:
storing data words and respective associated error correction codes in a local memory coupled to a processor included in the processor system;
retrieving, by an error detection and correction circuit, a selected data word and associated error code from the local memory;
forwarding, by the error detection and correction circuit, the selected data word to the processor if the selected data word exhibits no error;
correcting, by the error detection and correction circuit using in-line error correction, the selected data word if the selected data word exhibits a correctable error to provide a corrected data word that is sent to both the processor and the local memory;
signaling, by the error detection and correction circuit, an uncorrectable error condition to an error controller if the selected data word exhibits an uncorrectable error; and
initiating, by the error controller, out-of-line error correction operations to correct correctable errors.

2. The method of claim 1, wherein a correctable error corresponds to the selected data word exhibiting one erroneous bit.

3. The method of claim 1, wherein an uncorrectable error condition corresponds to the selected data word exhibiting at least two erroneous bits.

4. The method of claim 1, wherein the error detection and correction circuit detects a correctable error in the selected data word and further determines that the selected data word relates to an invalid local memory address, and in response the error controller initiates the background error scrubbing operation to repair the in the local memory.

5. The method of claim 1, wherein the error detection and correction circuit detects a correctable error in the selected data word and further determines that the selected data word relates to a valid local memory address, and in response the error controller initiates a read modify write operation to correct the correctable error in the local memory.

6. The method of claim 1, wherein the error detection and correction circuit detects an uncorrectable error condition in the selected data word and in response halts and signals an error.

7. The method of claim 6, wherein the error controller initiates a direct memory access (DMA) operation to send a data word from a system memory port to the local memory to repair the local memory.

8. The method of claim 1, wherein the error controller periodically initiates background error scrubbing operations.

9. A processor system comprising:
a first processor;
a local memory that stores data words and respective associated error correction codes local to the first processor;
a system memory port for coupling to a system memory that stores data words and supplies data words to the local memory;
direct memory address (DMA) circuitry coupling the local memory to the system memory port;
error detection and correction circuitry, coupled to the local memory and the first processor and the DMA circuitry, that retrieves a selected data word from the local memory, the error correction and detection circuitry using in-line error correction to correct the selected data word if the selected data word exhibits a correctable error to provide a corrected data word that is sent to both the first processor and the local memory; and
an error controller, coupled to the error detection and correction circuitry, that receives error information from the error detection and correction circuitry, the error controller initiating out-of-line error correcting operations to correct correctable errors indicated by the error information received from the error detection and correction circuitry.

10. The processor system of claim 9, wherein a correctable error corresponds to the selected data word exhibiting one erroneous bit.

11. The processor system of claim 9, wherein a correctable error corresponds to the selected data word exhibiting one erroneous bit.

12. The processor system of claim 9, wherein the error detection and correction circuit detects a correctable error in the selected data word and further determines that the selected data word relates to an invalid local memory address, and in response the error controller initiates the background error scrubbing operation to repair the local memory.

13. The processor system of claim 9, wherein the error detection and correction circuit detects a correctable error in the selected data word and further determines that the selected data word relates to a valid local memory address, and in response the error controller initiates a read modify write operation to correct the correctable error in the local memory.

14. The processor system of claim 9, wherein the error detection and correction circuit detects an uncorrectable error in the selected data word and in response the error controller halts and signals an error.

15. The processor system of claim 14, wherein the error controller initiates a direct memory access (DMA) operation by the DMA circuitry to send a data word from the system memory port to the local memory to repair the local memory.

16. The processor system of claim 9, wherein the error controller periodically initiates background error scrubbing operations.

17. The processor system of claim 9, further comprising a second processor coupled to the system memory port.

18. An information handling system (IHS) comprising:
a first processor;
a local memory that stores data words and respective associated error correction codes local to the first processor;
a system memory that stores data words and supplies data words to the local memory;
direct memory address (DMA) circuitry coupling the local memory to the system memory;
error detection and correction circuitry, coupled to the local memory and the first processor and the DMA circuitry, that retrieves a selected data word from the local memory, the error correction and detection circuitry using in-line error correction to correct the selected data word if the selected data word exhibits a correctable error to provide a corrected data word that is sent to both the first processor and the local memory; and
an error controller, coupled to the error detection and correction circuitry, that receives error information from the error detection and correction circuitry, the error controller initiating out-of-line error correcting operations to correct correctable errors indicated by the error information received from the error detection and correction circuitry.

19. The IHS of claim 18, further comprising a second processor coupled to the system memory.

20. The IHS of claim 18, wherein the error detection and correction circuit detects a correctable error in the selected data word and further determines that the selected data word relates to an invalid local memory address, and in response the error controller initiates a background error scrubbing operation to repair the error.
